(19) United States
(12) Patent Application Publication
(10) Pub. No.: US 2012/0249215 A1
(43) Pub. Date: Oct. 4, 2012

(54) SWITCH CIRCUIT

(75) Inventor: MAO-SEN WANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/183,534

(22) Filed: Jul. 15, 2011

(30) Foreign Application Priority Data
Mar. 29, 2011 (CN) 201110076817.3

(51) Int. Cl. H03K 17/687

(52) U.S. Cl. 327/434

(57) ABSTRACT

A switch circuit for switching between a first storage and a second storage. The switch circuit includes a switch, a control circuit, a switch control chip, and a processing chip. The control circuit is connected to the switch, the first storage, and the second storage. The control circuit either transmits power from a power supply to the first or second storage according to the switch. The switch control chip is connected to the control circuit. The processing chip is connected to the switch control chip. The control circuit controls the switch control chip to either transmit data between the processing chip and the first storage in response to the power supply powering the first storage, or transmit data between the processing chip and the second storage in response to the power supply powering the second storage.

### BACKGROUND

1. Technical Field

The present disclosure relates to a switch circuit.

2. Description of Related Art

For protecting information stored in handheld devices, dual systems are used. Users can store important information in one system, and store general information in the other system. Only if the users have to read the important information, the users can operate the system which stores the important information. Software is generally used to switch the handheld device between the two systems. However, there are security risks.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a block diagram of an exemplary embodiment of a switch circuit.

FIGS. 2-7 are circuit diagrams of the switch circuit of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

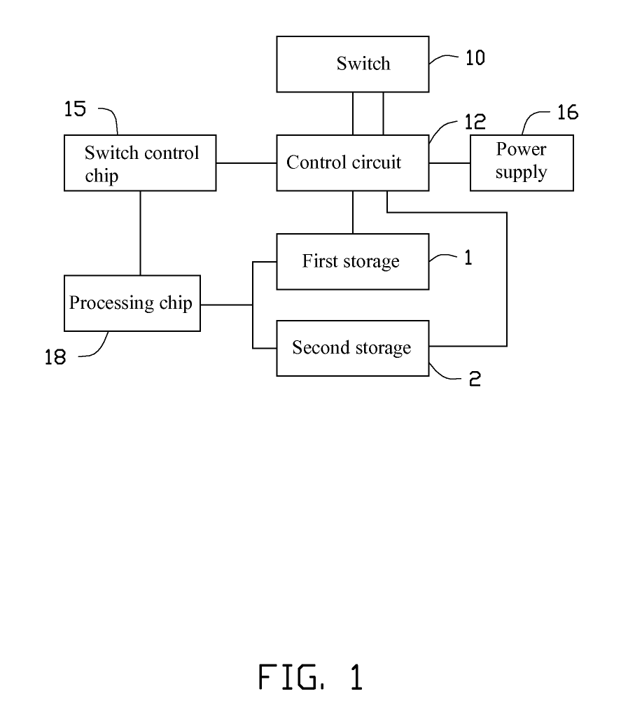

Referring to FIG. 1, an exemplary embodiment of a switch circuit includes a switch 10, a control circuit 12, a switch control chip 15, and a processing chip 18.

The switch 10 is connected to the control circuit 12. The control circuit 12 is connected to a first storage 1 and a second storage 2. The control circuit 12 is further connected to the power supply 16. The control circuit 12 either outputs power from a power supply 16 to the first storage 1 or outputs power from the power supply 16 to the second storage 2 according to the switch 10. The control circuit 12 is further connected to the switch control chip 15. The switch control chip 15 is connected to the processing chip 18. The control circuit 12 further either allows transmitting of data between the processing chip 18 and the first storage 1 or between the processing chip 18 and the second storage 2 according to the switch 10. In one embodiment, the power supply 16 supplies 3.3 volts (V).

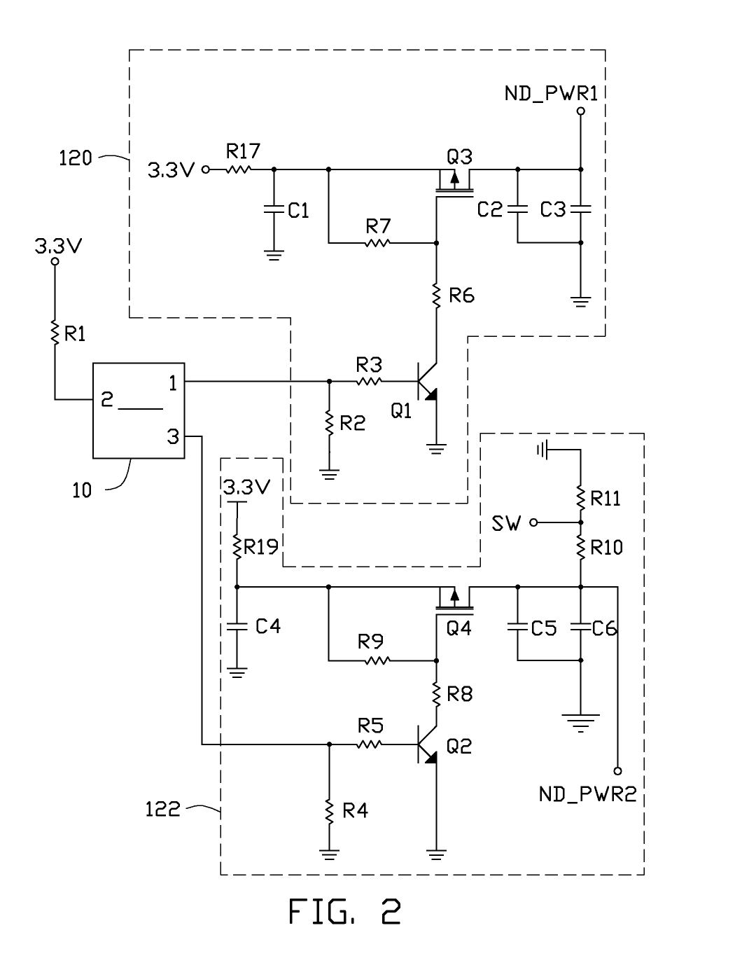

Referring to FIG. 2, the switch 10 is a single pole double throw switch. The control circuit 12 includes a first accessory circuit 120 and a second accessory circuit 122. A first end of a pole 2 of the switch 10 is connected to the power supply 3.3V through a resistor R1. A first throw 1 of the switch 10 is connected to the first accessory circuit 120. A second throw 3 of the switch 10 is connected to the second accessory circuit 122. When a second end of the pole 2 contacts the first throw 1, the first accessory circuit 120 supplies power to the first storage 100, and data can be transmitted between the processing chip 18 and the first accessory circuit 120. When the second end of the pole 2 contacts the second throw 2, the second accessory circuit 122 supplies power to the second storage 2, and data can be transmitted between the processing chip 18 and the second accessory circuit 122.

The first accessory circuit 120 includes a transistor Q1 and a transistor Q3. The second accessory circuit 122 includes a transistor Q2 and a transistor Q4. In one embodiment, the transistors Q1 and Q2 are npn transistors, and the transistors Q3 and Q4 are P-channel metal oxide semiconductor field effect transistors (MOSFETs).

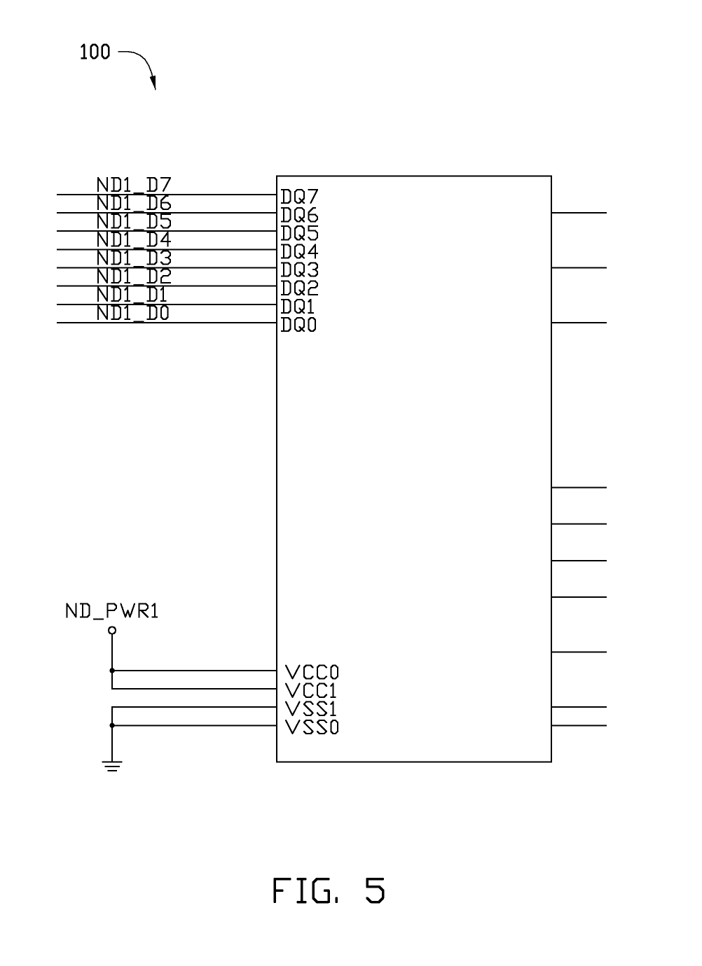

The first throw 1 of the switch 10 is grounded through a resistor R2. The first throw 1 is further connected to a base of the transistor Q1 through a resistor R3. The second throw 3 is grounded through a resistor R4. The second throw 3 is further connected to a base of the transistor Q2 through a resistor R5. An emitter of the transistor Q1 is grounded. A collector of the transistor Q1 is connected to a gate of the transistor Q3 through a resistor R6. The collector of the transistor Q1 is connected to the power supply 3.3V through two resistors R7 and R17 connected in series. A node between the resistors R7 and R17 is grounded through a capacitor C1. A source of the transistor Q3 is connected to the node between the resistors R7 and R17. A drain of the transistor Q3 is grounded through capacitors C2 and C3 connected in parallel. The drain of the transistor Q3 is connected to power terminals VCC0 and VCC1 of the first storage 100 (shown in FIG. 5) for outputting a first power signal ND_PWR1 to the first storage 100.

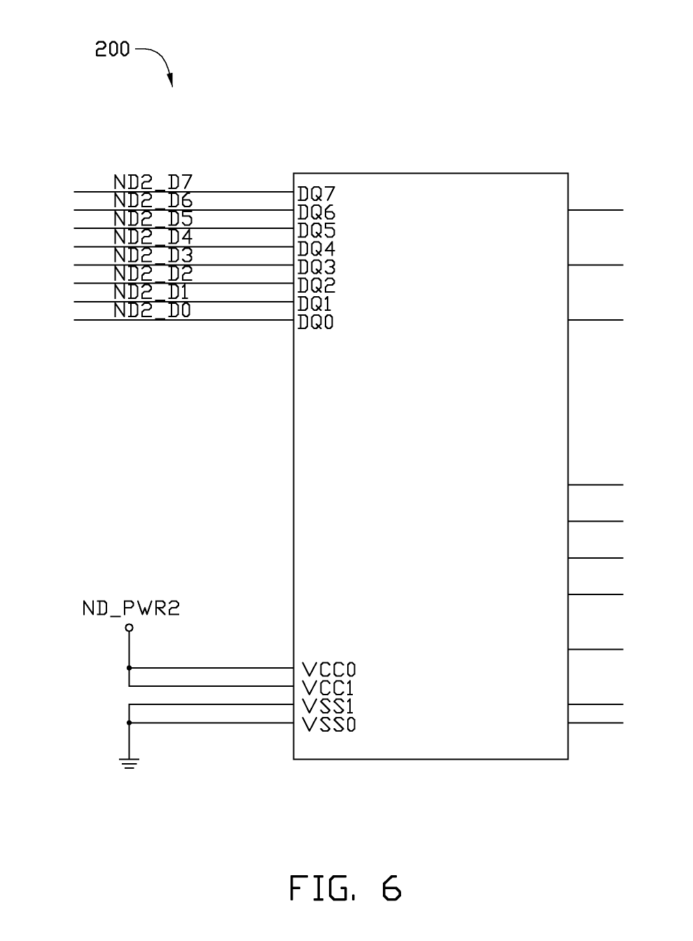

An emitter of the transistor Q2 is grounded. A collector of the transistor Q2 is connected to a gate of the transistor Q4 through a resistor R8. The collector of the transistor Q2 is connected to the power supply 3.3V through resistors R9 and R19 connected in series. A node between the resistors R9 and R19 is grounded through a capacitor C4. A source of the transistor Q4 is connected to the node between the resistors R9 and R19. A drain of the transistor Q4 is grounded through capacitors C5 and C6 connected in parallel. The drain of the transistor Q4 is connected to power terminals VCC0 and VCC1 of the second storage 200 (shown in FIG. 6) for outputting a second power signal ND_PWR2. The drain of transistor Q4 is grounded through resistors R10 and R11 connected in series. A node between the resistors R10 and R11 outputs a control signal SW.

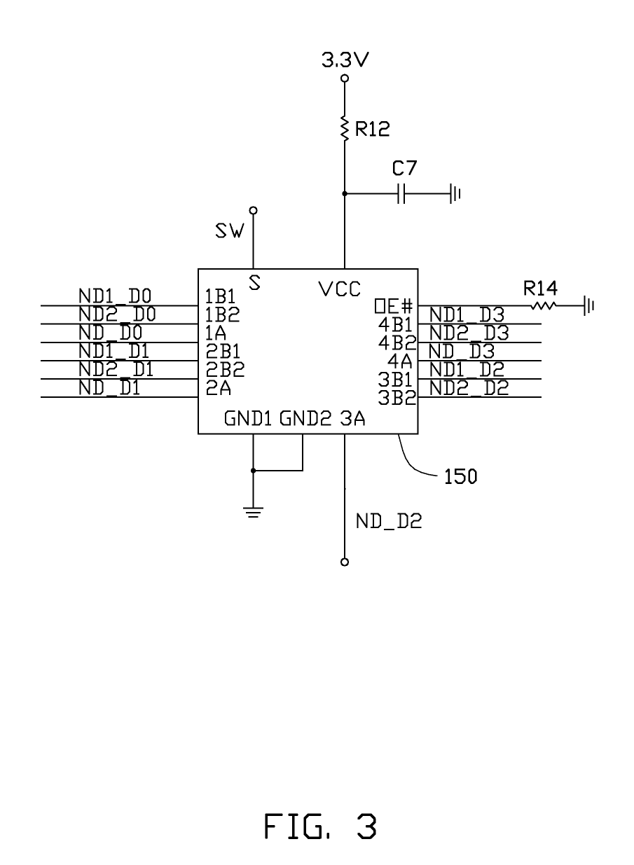

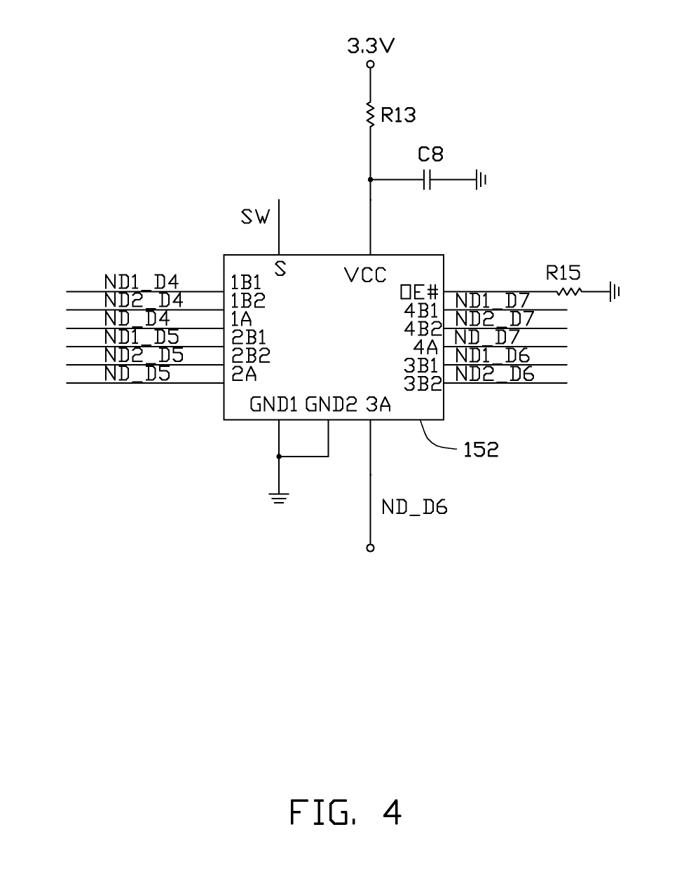

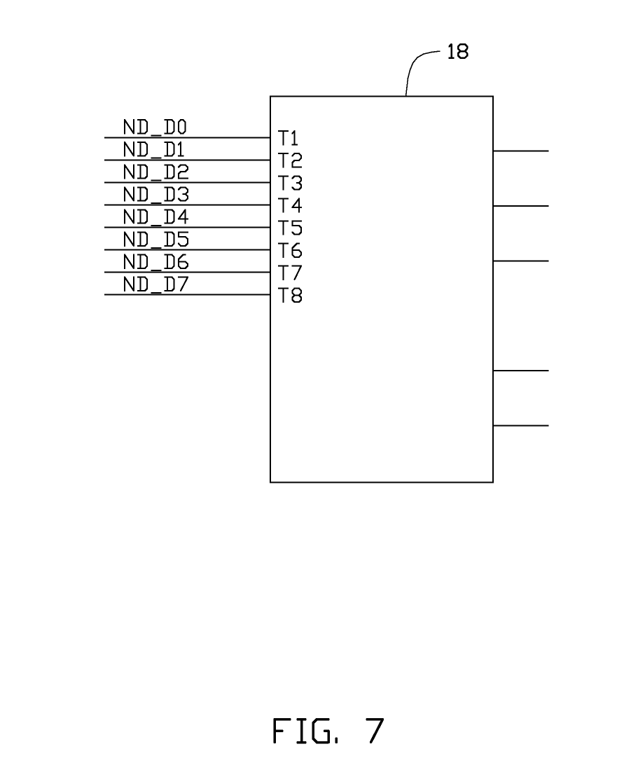

Referring to FIGS. 3 to 7, the switch control chip 15 includes a first control chip 150 and a second control chip 152. A power terminal VCC of the first control chip 150 is connected to the power supply 3.3V through a resistor R12, and is grounded through a capacitor C7. A power terminal VCC of the second control chip 152 is connected to the power supply 3.3V through a resistor R13, and is grounded through a capacitor C8. Control terminals S of the first control chip 150 and the second control chip 152 are connected to the node between the resistors R10 and R11, for receiving the control signal SW. Ground terminals GND1 and GND2 of the first control chip 150 and the second control chip 152 are grounded. An enable terminal OE# of the first control chip 150 is grounded through a resistor R14. An enable terminal OE# of the second control chip 152 is grounded through a resistor R15.

Data terminals 1A, 2A, 3A, and 4A of the first control chip 150 are respectively connected to data terminals T1, T2, T3, and T4 of the processing chip 18. Data terminals 1A, 2A, 3A, and 4A of the second control chip 152 are respectively connected to data terminals T5, T6, T7, and T8 of the processing chip 18. Data terminals 1B1, 2B1, 3B1, and 4B1 of the first control chip 150 are respectively connected to data terminals DQ0, DQ1, DQ2, and DQ3 of the first storage 100. Data terminals 1B1, 2B1, 3B1, and 4B1 of the second control chip 152 are respectively connected to data terminals DQ4, DQ5, DQ6, and DQ7 of the first storage 100. Data terminals 1B2, 2B2, 3B2, and 4B2 of the first control chip 150 are respectively connected to data terminals DQ0, DQ1, DQ2, and DQ3 of the second storage 200. Data terminals 1B2, 2B2, 3B2, and 4B2 of the second control chip 152 are respectively connected to data terminals DQ4, DQ5, DQ6, and DQ7 of the second storage 200.

When the pole 2 contacts the first throw 1, the base of the transistor Q1 receives a high level signal, and the base of the transistor Q2 receives a low level signal. At this time, the transistors Q1 and Q3 are turned on. The drain of the transistor Q3 outputs a high level signal. The first storage 100 is powered on. The transistors Q2 and Q4 are turned off. The drain of the transistor Q4 outputs a low level signal. The second storage 200 is not powered on.

In addition, each of the control terminals S of the first control chip 150 and the second control chip 152 receives a low level signal. Moreover, each of the enable terminals OE# of the first control chip 150 and the second control chip 152 is grounded. At this time, the data terminals 1A, 2A, 3A, and 4A of the first control chip 150 are respectively connected to the data terminals 1B1, 2B1, 3B1, and 4B1 of the first control chip 150. The data terminals 1A, 2A, 3A, and 4A of the second control chip 152 are respectively connected to the data terminals 1B1, 2B1, 3B1, and 4B1 of the second control chip 152. As a result, the data terminals T1-T8 of the processing chip 18 are respectively connected to the data terminals DQ0-DQ7 of the first storage 100. In other words, data can be transmitted between the first storage 100 and the processing chip 18.

When the pole 2 contacts the second throw 3, the base of the transistor Q1 receives a low level signal, and the base of the transistor Q2 receives a high level signal. At this time, the transistors Q1 and Q3 are turned off. The drain of the transistor Q3 outputs a low level signal. The first storage 100 is not powered on. The transistors Q2 and Q4 are turned on. The drain of the transistor Q4 outputs a high level signal. The second storage 200 is powered on.

In addition, each of the control terminals S of the first control chip 150 and the second control chip 152 receives a high level signal. Moreover, each of the enable terminals OE# of the first control chip 150 and the second control chip 152 is grounded. At this time, the data terminals 1A, 2A, 3A, and 4A of the first control chip 150 are respectively connected to the data terminals 1B2, 2B2, 3B2, and 4B2 of the first control chip 150. The data terminals 1A, 2A, 3A, and 4A of the second control chip 152 are respectively connected to the data terminals 1B2, 2B2, 3B2, and 4B2 of the second control chip 152. As a result, the data terminals T1-T8 of the processing chip 18 are respectively connected to the data terminals DQ0-DQ7 of the second storage 200. In other words, data can be transmitted between the second storage 200 and the processing chip 18.

The foregoing description of the exemplary embodiments of the disclosure has been presented only for the purposes of illustration and description and is not intended to be exhaustive or to limit the disclosure to the precise forms disclosed. Many modifications and variations are possible in light of the above everything. The embodiments were chosen and described in order to explain the principles of the disclosure and their practical application so as to enable others of ordinary skill in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A switch circuit for switching between a first storage and a second storage, the switch circuit comprising:
a switch;
a control circuit connected to the switch, the first storage, and the second storage, wherein the control circuit either transmits power from a power supply to the first or the second storage according to the switch;
a switch control chip connected to the control circuit; and
a processing chip connected to the switch control chip, wherein the control circuit controls the switch control chip to either transmit data between the processing chip and the first storage in response to the power supply powering the first storage, or transmit data between the processing chip and the second storage in response to the power supply powering the second storage.

2. The switch circuit of claim 1, wherein the switch is a single pole double throw switch, the control circuit comprises a first accessory circuit and a second accessory circuit, a pole of the switch is connected to the power supply, a first throw of the switch is connected to the first accessory circuit, a second throw of the switch is connected to the second accessory circuit, wherein when the pole is connected to the first throw, the first accessory circuit transmits power from the power supply to the first storage, and controls the switch control chip to transmit data between the processing chip and the first storage; wherein when the pole is connected to the second throw, the second accessory circuit transmits power from the power supply to the second storage, and controls the switch control chip to transmit data between the processing chip to the second storage.

3. The switch circuit of claim 2, wherein the first accessory circuit comprises a first transistor and a second transistor, the second accessory circuit comprises a third transistor and a fourth transistor, a base of the first transistor is connected to the first throw of the switch through a first resistor, an emitter of the first transistor is grounded, a collector of the first transistor is connected to a gate of the second transistor through a second resistor, a source of the second transistor is connected to the power supply, a drain of the second transistor is connected to a power terminal of the first storage; a base of the third transistor is connected to the second throw of the switch through a third resistor, an emitter of the third transistor is grounded, a collector of the third transistor is connected to a gate of the fourth transistor through a fourth resistor, a source of the fourth transistor is connected to the power supply, a drain of the fourth transistor is connected to a power terminal of the second storage and the switch control chip.

4. The switch circuit of claim 1, wherein the switch control chip comprises a first control chip and a second control chip, control terminals of the first and second control chips are connected to the control circuit, enable terminals of the first and second control chip are grounded, a first group of data terminals of the first control chip are respectively connected to a first group of data terminals of the processing chip, a second group of data terminals of the first control chip are respectively connected to a first group of data terminals of the first storage, a third group of data terminals of the first control chip are respectively connected to a second group of data terminals of the first storage, a first group of data terminals of the second control chip are respectively connected to a second group of data terminals of the processing chip, a second group of data terminals of the second control chip are respectively connected to a first group of data terminals of the second storage, a third group of data terminals of the second control chip are respectively connected to a second group of data terminals of the second storage; when the control terminal of the first control chip receives a low level signal, the first group of data terminals of the first control chip are respectively connected to the second group of data terminals of the first control chip, when the control terminal of the first control chip receives a high level signal, the first group of data terminals of the first control chip are respectively connected to the third group of data terminals of the first control chip; when the control terminal of the second control chip receives a low level signal, the first group of data terminals of the second control chip are respectively connected to the second group of data terminals of the second control chip, when the control terminal of the first control chip receives a high level signal, the first group of data terminals of the second control chip are respectively connected to the third group of data terminals of the second control chip.
